(19) United States
(12) Patent Application Publication
(10) Pub. No.: US 2008/0124528 A1
(43) Pub. Date: May 29, 2008

(54) PRINTED ELECTRONIC DEVICE AND METHODS OF DETERMINING THE ELECTRICAL VALUE THEREOF

(75) Inventors: Jerzy Wielgus, Mount Prospect, IL (US); Daniel R. Gamota, Palatine, IL (US); John B. Szczech, Schaumburg, IL (US); Jie Zhang, Buffalo Grove, IL (US)

Correspondence Address: MOTOROLA, INC., 1303 EAST ALGONQUIN ROAD, IL01/3RD, SCHAUMBURG, IL, 60196, US

(73) Assignee: MOTOROLA, INC., Schaumburg, IL (US)

(21) Appl. No.: 11/564,703

(22) Filed: Nov. 29, 2006

(51) Int. Cl. H05K 1/16; H05K 3/46

(52) U.S. Cl. 428/206; 427/10; 428/195.1

(57) ABSTRACT

A printed electronic device and methods for determining the electrical value of the device. A dielectric material is contact printed on a substrate using a preset force. The substrate has a pressure sensitive material that is optically responsive in direct proportion to the amount of force imparted by the contact printing. The force of the contact printing causes the pressure sensitive material to form a pattern that is quantifiable to the amount of force. The pattern is then optically inspected and compared to sets of standards in order to quantify the amount of force that was used in printing. The thickness of the printed dielectric material is then calculated based on the quantified force by comparing to another set of standards. The electrical value of the printed material is calculated based on the calculated thickness of the printed dielectric material, the surface area of the printed dielectric material, and the dielectric constant of the dielectric material.

### FIELD OF THE INVENTION

The present invention relates generally to printed electrical circuitry, and more particularly, to a printed electronic device and methods of measuring the value of electronic devices that are formed by contact printing.

### BACKGROUND

Conventional fabrication methods for printed circuits have always utilized one or more methods of creating a conductive metal pattern on a dielectric substrate. Some of the various methods include print and etch, electroless copper deposition, vacuum deposition, and screen printing, contact printing, or ink jetting a liquid slurry of metal onto the substrate. Some of these methods are subtractive, such as the print and etch where patterns are etched from a laminated copper foil, others are purely additive, such as the printing or ink jetting methods where conductor patterns are directly formed on the substrate, and still others are combinations of additive and subtractive. In addition to forming conductor patterns for the electrical circuitry, many have also sought to create passive devices, such as resistors and capacitors, on the substrate. Resistors and capacitors have long been utilized with success in circuits with ceramic substrates, and some have even modified this technology to incorporate it into circuitry on rigid glass reinforced polymer substrates, such as epoxy-glass and polyimide-glass. Adoption of passive devices on high volume, low cost, flexible film substrates has been less successful. Fabrication of printed electronic circuitry and devices using graphic arts technology has the potential to produce very inexpensive circuits in very high volumes. However, quality control of printed electronics during fabrication has been difficult, if not impossible, using high throughput graphics arts printing technology, due to the lack of on-press functional test capability. Conventional quality control techniques for measuring tolerances of resistors and capacitors utilize combinations of mechanical and electrical testing after the devices are completely fabricated. In the low volume factories of the past, this was acceptable, as process changes could be made before numerous off-specification parts were made. However, in the high volume world of the future, ‘after-the-fact’ testing will be financially disastrous, as errors during processing would create a large amount of defective product before the error was even detected. A more rapid means of measuring and testing printed electronic devices would be a significant contribution to the art.

### BRIEF DESCRIPTION OF THE FIGURES

The accompanying figures, where like reference numerals refer to identical or functionally similar elements throughout the separate views and which together with the detailed description below are incorporated in and form part of the specification, serve to further illustrate various embodiments and to explain various principles and advantages all in accordance with the present invention.

FIG. 1 is a cross sectional view of a printed electronic device, in accordance with some embodiments of the invention.

FIG. 2 is a flow chart depicting a process for monitoring the capacitance value of printed capacitors, in accordance with some embodiments of the invention.

FIG. 3 is a graph of dielectric thickness as a function of printing force, in accordance with some embodiments of the invention.

FIG. 4 is a graph of capacitance as a function of printed dielectric thickness, in accordance with some embodiments of the invention.

FIG. 5 is a stylized image map of pressure sensitive indicia after being subjected to contact printing force, in accordance with some embodiments of the invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION

Before describing in detail embodiments that are in accordance with the present invention, it should be observed that the embodiments reside primarily in combinations of methods and apparatus components related to printed electronic devices that are formed by contact printing.

Accordingly, the apparatus components and methods have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

In this document, relational terms such as first and second, top and bottom, and the like may be used solely to distinguish one entity or action from another entity or action without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “comprises . . . a” does not, without more constraints, preclude the existence of additional identical elements in the process, method, article, or apparatus that comprises the element. The terms “printed electronics” and “printed electronic device” are intended to include both active and passive devices such as capacitors, resistors, inverters, ring oscillators, transistors, etc. that are formed by contact printing one or more elements of the device on a substrate, in contrast to the discrete devices produced by, for example semiconductor technology on wafers or ceramic thick film firing techniques.

It will be appreciated that embodiments of the invention described herein may be comprised of one or more conventional materials or processes. Thus, methods and means for these functions have been described herein. Further, it is expected that one of ordinary skill, notwithstanding possibly significant effort and many design choices motivated by, for example, available time, current technology, and economic considerations, when guided by the concepts and principles disclosed herein will be readily capable of using the measuring technique disclosed herein with minimal experimentation.

A method for determining the electrical value of printed electronic devices comprises contact printing a dielectric material on a substrate using a preset force. The substrate has a pressure sensitive material that comprises indicia that are optically responsive in direct proportion to the amount of force imparted by the contact printing step. The force of the contact printing step causes the indicia to form a pattern that is quantifiable to the amount of force. The pattern is then optically inspected and compared to one or more sets of previously made standards in order to quantify the amount of force that was used to contact print the dielectric material. The thickness of the printed dielectric material is then calculated based on the quantified force by comparing to another set of standards. The electrical value of the printed material can then be calculated based on the calculated thickness of the printed dielectric material, the surface area of the printed dielectric material, and the dielectric constant of the dielectric material.

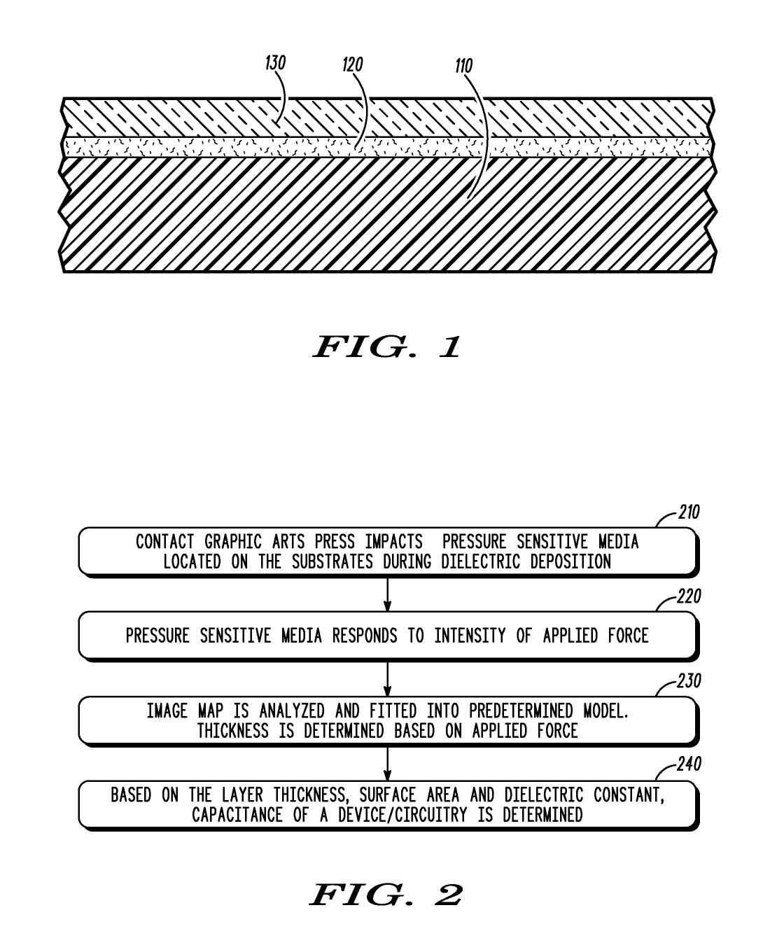

In order to illustrate the invention, a method of printing capacitors on a film will now be illustrated. It should be understood that while this embodiment is provided to aid the reader in understanding the invention, it is not intended to be limiting, but is presented as one example of our invention. Referring now to FIG. 1, a dielectric substrate 110 has a pressure sensitive media 120 disposed thereon, the pressure sensitive media comprising a material that is optically responsive in direct proportion to the amount of force imparted thereto. The dielectric substrate 110 is typically a flexible film, such as polyester or polyimide, polyamide, polyethylene terephthalate, or various blends thereof. The pressure sensitive media can be disposed within the substrate, for example, by incorporating it into the film matrix, or it can be disposed on the surface of the substrate, for example, by coating the substrate with the material, or by laminating a film containing the pressure sensitive media onto the substrate. In the latter case, commercially available films containing the pressure sensitive material are available from, for example, Fujifilm Corporation of Japan, under the product name of Prescale film. Prescale film is distributed in the United States by Sensor Products LLC of Madison, N.J., under the product name of PRESSUREX®. This example of an optically responsive indicia employs a polyethylene terephthalate film containing a pressure sensitive adhesive on one side and a micro encapsulated dye that ruptures under a predetermined amount of force on the other side, creating an instantaneous and permanent high resolution topographical image of pressure variation across the contact area. The amount of the various micro-encapsulants that rupture varies as a function of force imparted, so that the color intensity of the image is directly related to the amount of force applied to the media. The referenced pressure sensitive media is commercially available in seven (7) pressure ranges, allowing one to measure forces from 0.2 MPa to 130 MPa. This allows one to tailor the system so that a unique color pattern is revealed when a given force is imparted upon the media. For example, a force of 1 MPa will create a first color pattern, and a force of 10 MPa will create a second, unique, discernible pattern. Other indicia can be used to measure forces ranging from 0.01 to 300 MPa.

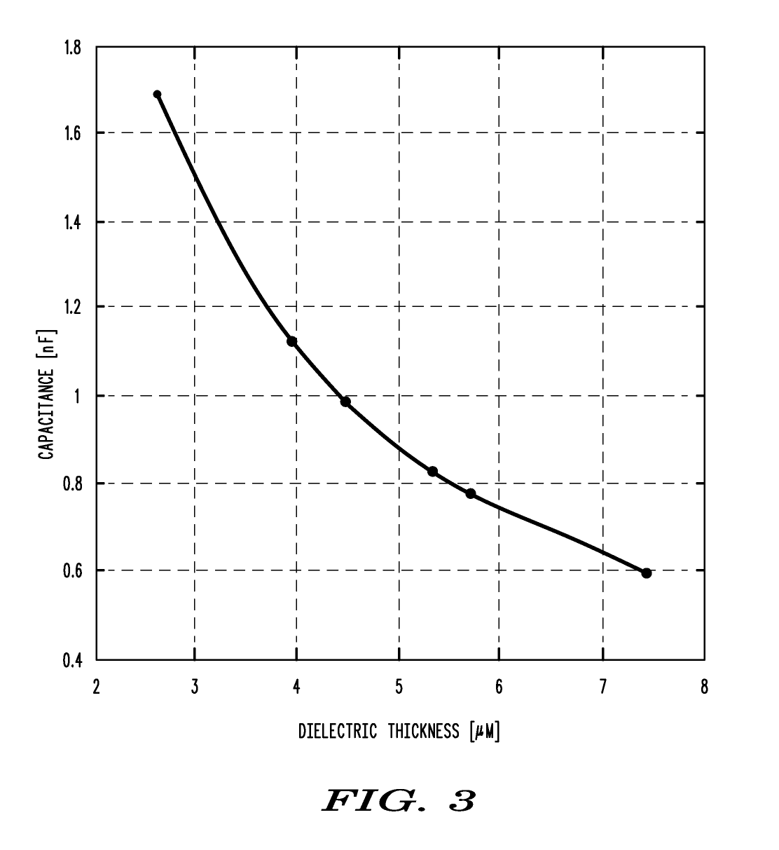

Referring now to FIG. 1 and the flowchart depicted in FIG. 2, a dielectric material 130, such as an acrylic polymer thick film dielectric is contact printed on the pressure sensitive media using a graphic arts press 210. One type of printed dielectric is a material that can be used to form the inner dielectric layer of a capacitor. Other types of printed electronic devices that can be produced using the methods of our invention include resistors, inverters, ring oscillators, and transistors. The pressure sensitive media 120 is typically laminated to a film carrier substrate 110 by means of a pressure sensitive adhesive, or it can be coated or otherwise applied to the film carrier substrate. Some examples of suitable printing technologies are screen printing, gravure printing, offset printing, and flexography. During the printing process, the head of the press impacts the pressure sensitive media 120 with a certain amount of force, which is typically an amount that is predetermined so as to produce the desired pattern of dielectric material in a selected area. Contact printing typically employs a platen that is inked in a pattern with the material to be printed, and then contacted to the substrate with a certain amount of force. Those familiar with high speed graphic arts printing technology will realize that the quality of the printed image (in this case, the printed dielectric material) is a function of several variables, one of the most important being the amount of force (pressure of the contact head) that is used to contact the substrate. That is, a low amount of pressure (force) will yield a thin coating, with higher forces creating a continuing thicker material, until a very thick coating is produced at high pressure. Unlike the graphic arts industry, the materials used in the electronics industry are often colorless or transparent, thus visual intensity cannot be used as an indication of printed thickness. The thickness of the capacitive material in printed capacitors directly affects the capacitance value of the finished product, so the thickness of the printed material must be precisely controlled and monitored in order to insure that the capacitor will be exactly the specified value. Simply adjusting the pressure of the contact printing press does not insure that the thickness will be of the proper amount, nor does it provide an ongoing method to control the thickness. The pressure sensitive media responds in direct proportion to the intensity of the applied force 220 as the micro encapsulants rupture under pressure to release the dye and form a pattern or image that is representative of the amount of force applied. The color or size of the pattern produced by the optically responsive media is measured through the printed material using well known computerized vision inspection systems to provide a closed loop feedback on the thickness of the printed material. The computerized vision inspection image obtained on the printed dielectric material is compared 230 to one or more sets of standard images that were previously prepared using strictly calibrated forces on the pressure sensitive media, and the amount of force that was actually imparted by the contact printing press on the substrate can thus be accurately determined. Once the level of force used has been determined, the thickness of the printed dielectric material is then determined, based on reference to a second set of standards. Like the first set of standards, these standards have been empirically determined using known, documented materials in laboratory conditions. FIG. 3 is a graph of printed dielectric thickness as a function of force used to print a selected dielectric material on a substrate. Note that between printed thickness of less than 3 microns to over 7 microns, the variation in thickness is nearly linear, enabling one to accurately measure the amount of material actually deposited by simply measuring the amount of force imparted upon the pressure sensitive media. Once the thickness has been accurately determined, the capacitance of the material is calculated based on the calculated thickness of the printed capacitive material, the surface area of the printed capacitive material, and the dielectric constant of the capacitive material 240. The capacitance can be calculated by:

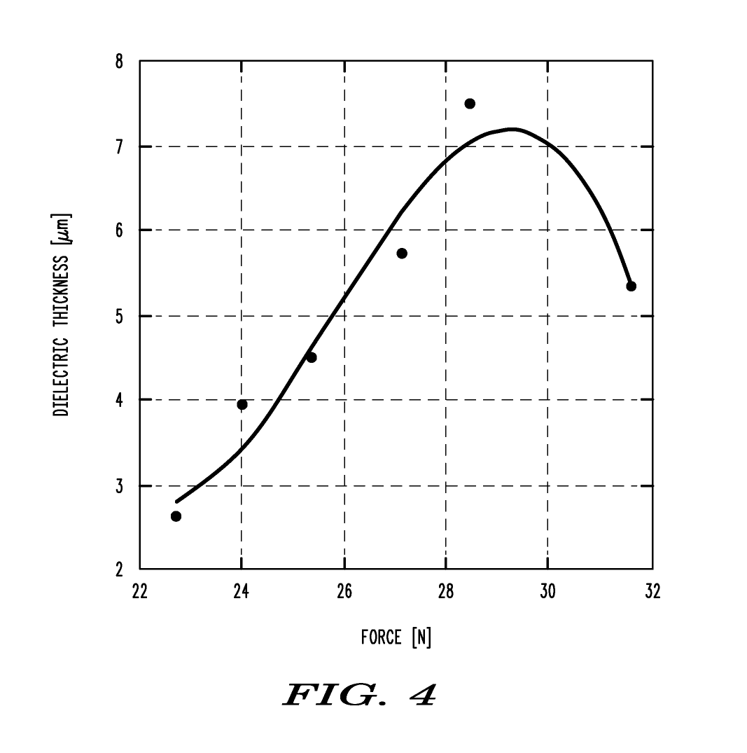

C=(E₀×K×S)/T

where C is capacitance of the printed dielectric material, E₀ is 8.8×10⁻¹² farads per meter (vacuum permittivity), K is the dielectric constant of the printed dielectric material, S is the area of the printed dielectric material in square meters, and T is the calculated thickness of the printed dielectric material based on the measured force. FIG. 4 is a graph depicting the capacitance as a function of printed dielectric thickness for the selected capacitors depicted in FIG. 3.

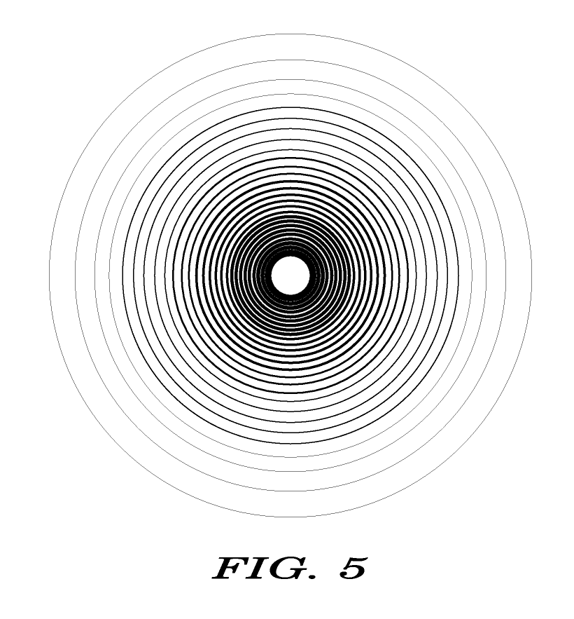

Referring now to FIG. 5, a stylized representation of the image produced when a dielectric material is contact printed on a pressure sensitive indicia in a rectangular pattern, the force used to contact the substrate causes the dye to produce a pattern whose intensity determines the thickness of the printed material. In the drawing, darker areas indicate more force, and lighter, less shaded areas indicate less force.

In summary, the electrical value of printed electronic devices can be indirectly determined by using optical inspection means to indirectly measure the amount of force used to contact print a dielectric material, then calculating the thickness of the printed material by referencing the calculated force. Once the thickness, area, and dielectric constant are known, the electrical value can be calculated.

In the foregoing specification, specific embodiments of the present invention have been described. However, one of ordinary skill in the art appreciates that various modifications and changes can be made without departing from the scope of the present invention as set forth in the claims below. For example, one would also print a series of conductive patterns or circuit traces on the carrier substrate using silver-filled, carbon-filled, or an intrinsicaly conductive polymer ink, in any one of several conventional methods, to form resistors or capacitors in selected locations. Accordingly, the specification and figures are to be regarded in an illustrative rather than a restrictive sense, and all such modifications are intended to be included within the scope of present invention. The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

What is claimed is:

1. A method of manufacturing printed electronic devices on a substrate, comprising:
providing a substrate having pressure sensitive media comprising indicia that is optically responsive to a force;
contact printing a dielectric material on the pressure sensitive media using an applied force, so as to cause the indicia to respond;
optically inspecting the responded indicia and comparing to predetermined standards in order to quantify the amount of applied force used to print the dielectric material;
calculating the thickness of the printed dielectric material based on the quantified applied force; and
calculating the electrical value of the printed material based on the calculated thickness of the printed dielectric material, the surface area of the printed dielectric material, and the dielectric constant of the dielectric material.

2. The method as described in claim 1, wherein the indicia comprises one or more micro-encapsulated dyes.

3. The method as described in claim 1, wherein the indicia is responsive to forces between 0.01 mega Pascal and 300 mega Pascal.

4. The method as described in claim 1, wherein the electronic device comprises one or more items selected from the group consisting of capacitors, resistors, inverters, ring oscillators, and transistors.

5. The method as described in claim 1, wherein the one or more sets of predetermined standards comprises a plurality of pressure sensitive media, each having been impacted by a force of known amount, and each force being a different amount.

6. The method as described in claim 1, wherein the printed electronic device is a capacitor, and the calculated electrical value is:
C=(E₀×K×S)/T
where C is capacitance of the printed dielectric material, E₀ is 8.8×10⁻¹² farads per meter (vacuum permittivity), K is the dielectric constant of the printed dielectric material, S is the area of the printed dielectric material in square meters, and T is the calculated thickness of the printed dielectric material based on the measured force.

7. A method of manufacturing printed capacitors on a substrate, comprising:
providing a substrate having pressure sensitive media comprising micro-encapsulated dye that is optically responsive to a force;
contact printing a capacitive material on the pressure sensitive media using an applied force, so as to cause the micro-encapsulated dye to form a pattern;
optically inspecting the pattern and comparing to predetermined standard patterns to quantify the amount of applied force used to print the capacitive material;
calculating the thickness of the printed capacitive material based on the quantified applied force; and
calculating the capacitance of the printed material based on the calculated thickness of the printed capacitive material, the surface area of the printed capacitive material, and the dielectric constant of the capacitive material.

8. The method as described in claim 7, wherein contact printing comprises one or more printing techniques selected from the group consisting of screen printing, gravure printing, offset printing, and flexography.

9. The method as described in claim 7, wherein the indicia is responsive to forces between 0.01 mega Pascal and 300 mega Pascal.

10. The method as described in claim 7, wherein the one or more sets of predetermined standards comprises a plurality of pressure sensitive media, each having been impacted by a force of known amount, and each force being a different amount.

11. The method as described in claim 7, wherein the calculated capacitance is:
C=(E₀×K×S)/T
where C is capacitance of the printed dielectric material, E₀ is 8.8×10⁻¹² farads per meter (vacuum permittivity), K is the dielectric constant of the printed dielectric material, S is the area of the printed dielectric material in square meters, and T is the calculated thickness of the printed dielectric material based on the measured force.

12. A method of determining the electrical value of printed electronic devices, comprising:
contact printing a dielectric material on a substrate using a selected force, the substrate having pressure sensitive indicia that is optically responsive in direct proportion to the amount of force imparted thereupon, the force causing the indicia to form a pattern;
optically inspecting the formed pattern and comparing it to one or more sets of predetermined standards in order to quantify the amount of force used to contact print the dielectric material;
calculating the thickness of the printed dielectric material based on the quantified force using an algorithm; and
calculating the electrical value of the printed material based on the calculated thickness of the printed dielectric material, the surface area of the printed dielectric material, and the dielectric constant of the dielectric material.

13. The method as described in claim 12, wherein contact printing comprises one or more printing techniques selected from the group consisting of screen printing, gravure printing, offset printing, and flexography.

14. The method as described in claim 12, wherein the pressure sensitive indicia comprises one or more micro-encapsulated dyes.

15. The method as described in claim 12, wherein the indicia is responsive to forces between 0.01 mega Pascal and 300 mega Pascal.

16. The method as described in claim 12, wherein the electronic device comprises one or more items selected from the group consisting of capacitors, resistors, inverters, ring oscillators, and transistors.

17. The method as described in claim 12, wherein the one or more sets of predetermined standards comprises a plurality of pressure sensitive media, each having been impacted by a force of known amount, and each force being a different amount.

18. The method as described in claim 12, wherein the printed electronic device is a capacitor, and the calculated electrical value is:
C=(E₀×K×S)/T
where C is capacitance of the printed dielectric material, E₀ is 8.8×10⁻¹² farads per meter (vacuum permittivity), K is the dielectric constant of the printed dielectric material, S is the area of the printed dielectric material in square meters, and T is the calculated thickness of the printed dielectric material based on the measured force.

19. A printed electronic device on a substrate, comprising:
an insulating substrate comprising pressure indicating media, said media comprising indicia that is optically responsive to a contacting force;
a dielectric material printed on one or more portions of the pressure indicating media using a contact force sufficient to cause the pressure indicating media to form an optically measurable pattern that is quantifiable to the contact force; and
wherein the printed dielectric material is a portion of an electronic device selected from the group consisting of capacitors, resistors, inverters, ring oscillators, and transistors.

20. The printed electronic device as described in claim 19, wherein the pressure indicating media comprises one or more micro-encapsulated dyes.
